(19) United States
(12) Patent Application Publication
(10) Pub. No.: US 2018/0323208 A1
(43) Pub. Date: Nov. 8, 2018

(54) VERTICAL DIVISION OF THREE-DIMENSIONAL MEMORY DEVICE

(71) Applicant: Cypress Semiconductor Corporation, San Jose, CA (US)

(72) Inventors: Rinji Sugino, San Jose, CA (US); Scott A. Bell, San Jose, CA (US); Lei Xue, Saratoga (US)

(73) Assignee: Cypress Semiconductor Corporation, San Jose, CA (US)

(21) Appl. No.: 16/020,546

(22) Filed: Jun. 27, 2018

Related U.S. Application Data
(63) Continuation of application No. 14/966,321, filed on Dec. 11, 2015.
(60) Provisional application No. 62/212,220, filed on Aug. 31, 2015.

(51) Int. Cl. H01L 27/11582; H01L 27/11565; G11C 16/04

(52) U.S. Cl. CPC H01L 27/11582; G11C 16/0483; H01L 27/11565

(57) ABSTRACT

A method of forming a vertical non-volatile (NV) memory device such as 3-D NAND flash memory includes forming a vertical NV memory cell string within an opening disposed in a stack of alternating layers of a first layer and a second layer over a substrate, and dividing the vertical NV memory cell string into two halves with a first vertical deep trench and an isolation dielectric pillar formed in the first vertical deep trench, such that memory bit density of the divided vertical NV memory cell strings double the memory bits of the device.

### PRIORITY

This application is a Continuation Application of U.S. patent application Ser. No. 14/966,321, filed on Dec. 11, 2015, which claims the priority and benefit under 35 U.S.C. § 119(e) of U.S. Provisional Application No. 62/212,220, filed on Aug. 31, 2015, all of which are incorporated by reference herein in their entirety.

### TECHNICAL FIELD

The present disclosure relates generally to non-volatile (NV) memory devices, and more particularly to three-dimensional (3D) or vertical NV memory cell strings and methods of manufacturing thereof including dividing vertical memory cell strings to enhance memory bit density and integrity.

### BACKGROUND

Flash memory, both the NAND and NOR types, includes strings of NV memory elements or cells, such as floating-gate metal-oxide-semiconductor field-effect (FGMOS) transistors and silicon-oxide-nitride-oxide-silicon (SONOS) transistors. The fabrication of two-dimensional or planar flash memory devices is down to 10 nm lithography, and the reduction in scale has started to create issues as each NV memory element is getting smaller and physically closer to one another. In these NV memory elements, their charge trapping gates hold much fewer electrical charges due to the smaller scale. As a result, any small imperfection in the fabrication process may cause logic/memory states of the NV memory elements to become difficult to differentiate, which may result in a false reading of logic states. Moreover, control electrodes are getting so small and closely spaced that their effects, such as in biasing gates, may spread over more than one memory cells or strings, which may lead to unreliable reading and writing of data.

To overcome the limitations of available area on a semiconductor substrate, in 3D or vertical geometry, NV memory cell strings are oriented vertically and NV memory cells are stacked on a semiconductor substrate. Accordingly, memory bit density is much enhanced compared to the two-dimensional (2D) geometry, with a similar footprint on the substrate. In addition, using the 3D or vertical staking techniques, word-lines may be formed by using a patterning process to define an active region, thereby greatly reducing a manufacturing cost per stored memory bit.

### BRIEF DESCRIPTION OF THE DRAWINGS

The present disclosure is illustrated by way of example, and not by way of limitation, in the FIGS. of the accompanying drawings.

FIG. 1 is a flowchart illustrating an embodiment of a method for fabricating a vertical NV memory device including strings of NV memory cells;

FIGS. 2A and 2B are representative diagrams illustrating isometric views of a portion of a vertical NV memory device during fabrication according to the method of FIG. 1;

FIGS. 3A, 3B and 3C are representative diagrams illustrating cross-sectional views of a portion of a vertical NV memory device during fabrication according to the method of FIG. 1;

FIGS. 4A and 4B are representative diagrams illustrating a side and top cross-sectional views of a portion of a vertical NV memory device during fabrication according to the method of FIG. 1;

FIGS. 5A and 5B are representative diagrams illustrating a side and top cross-sectional views of a portion of a vertical NV memory device during fabrication according to the method of FIG. 1;

FIGS. 6A and 6B are representative diagrams illustrating a side and top cross-sectional views of a portion of a vertical NV memory device during fabrication according to the method of FIG. 1;

FIGS. 7A and 7B are representative diagrams illustrating a side and top cross-sectional views of a portion of a vertical NV memory device during fabrication according to the method of FIG. 1;

FIGS. 8A and 8B are representative diagrams illustrating a side and top cross-sectional views of a portion of a vertical NV memory device during fabrication according to the method of FIG. 1;

FIGS. 9A and 9B are representative diagrams illustrating a side and top cross-sectional views of a portion of a vertical NV memory device during fabrication according to the method of FIG. 1;

FIG. 10 is a representative diagram illustrating a top cross-sectional view of a portion of a vertical NV memory array/device during fabrication according to the method of FIG. 1;

FIGS. 11A and 11B are representative diagrams illustrating a top cross-sectional view and a schematic diagram of a portion of a vertical NV memory device during fabrication according to the method of FIG. 1;

FIGS. 12A and 12B are representative diagrams illustrating a top cross-sectional view and a schematic diagram of a portion of a vertical NV memory device during fabrication according to the method of FIG. 1;

FIG. 13 is a representative diagram illustrating a top cross-sectional view of a portion of a vertical NV memory device during fabrication according to the method of FIG. 1; and

FIG. 14 is a representative diagram illustrating a cross-sectional view of a portion of a finished vertical NV memory array/device including multiple vertical strings of NV memory cells fabricated according to the method of FIGS. 1 and 2A-13.

### DETAILED DESCRIPTION

The following description sets forth numerous specific details such as examples of specific systems, components, methods, and so forth, in order to provide a good understanding of several embodiments of the present subject matter. It will be apparent to one skilled in the art, however, that at least some embodiments may be practiced without these specific details. In other instances, well-known components or methods are not described in detail or are presented in a simple block diagram format in order to avoid unnecessarily obscuring the techniques described herein. Thus, the specific details set forth hereinafter are merely exemplary. Particular implementations may vary from these exemplary details and still be contemplated to be within the spirit and scope of the present subject matter.

Embodiments of a vertical or three-dimensional (3D) non-volatile (NV) memory device including strings of non-volatile memory (NVM) transistors and/or field-effect transistors (FET), and methods of fabricating the same are described herein with reference to figures. It is the understanding that NV memory includes memory devices that retain their states even when operation power is removed. While their states may eventually dissipate, they are retained for a relatively long time. However, particular embodiments may be practiced without one or more of these specific details, or in combination with other known methods, materials, and apparatuses. In the following description, numerous specific details are set forth, such as specific materials, dimensions, concentrations, and processes parameters etc. to provide a thorough understanding of the present subject matter. In other instances, well-known semiconductor design and fabrication techniques have not been described in particular detail to avoid unnecessarily obscuring the present subject matter. Reference in the description to “an embodiment”, “one embodiment”, “an example embodiment”, “some embodiments”, and “various embodiments” means that a particular feature, structure, or characteristic described in connection with the embodiment(s) is included in at least one embodiment of the subject matter. Further, the appearances of the phrases “an embodiment”, “one embodiment”, “an example embodiment”, “some embodiments”, and “various embodiments” in various places in the description do not necessarily all refer to the same embodiment(s).

The description includes references to the accompanying drawings, which form a part of the detailed description. The drawings show illustrations in accordance with exemplary embodiments. These embodiments, which may also be referred to herein as “examples,” are described in enough detail to enable those skilled in the art to practice the embodiments of the claimed subject matter described herein. The embodiments may be combined, other embodiments may be utilized, or structural, logical, and electrical changes may be made without departing from the scope and spirit of the claimed subject matter. It should be understood that the embodiments described herein are not intended to limit the scope of the subject matter but rather to enable one skilled in the art to practice, make, and/or use the subject matter.

The terms “over”, “overlying”, “under”, “between”, and “on” as used herein refer to a relative position of one layer with respect to other layers. As such, for example, one layer deposited or disposed over or under another layer may be directly in contact with the other layer or may have one or more intervening layers. Moreover, one layer deposited or disposed between layers may be directly in contact with the layers or may have one or more intervening layers. In contrast, a first layer “on” a second layer is in contact with that second layer. Additionally, the relative position of one layer with respect to other layers is provided assuming operations deposit, modify and remove films relative to a starting wafer without consideration of the absolute orientation of the wafer.

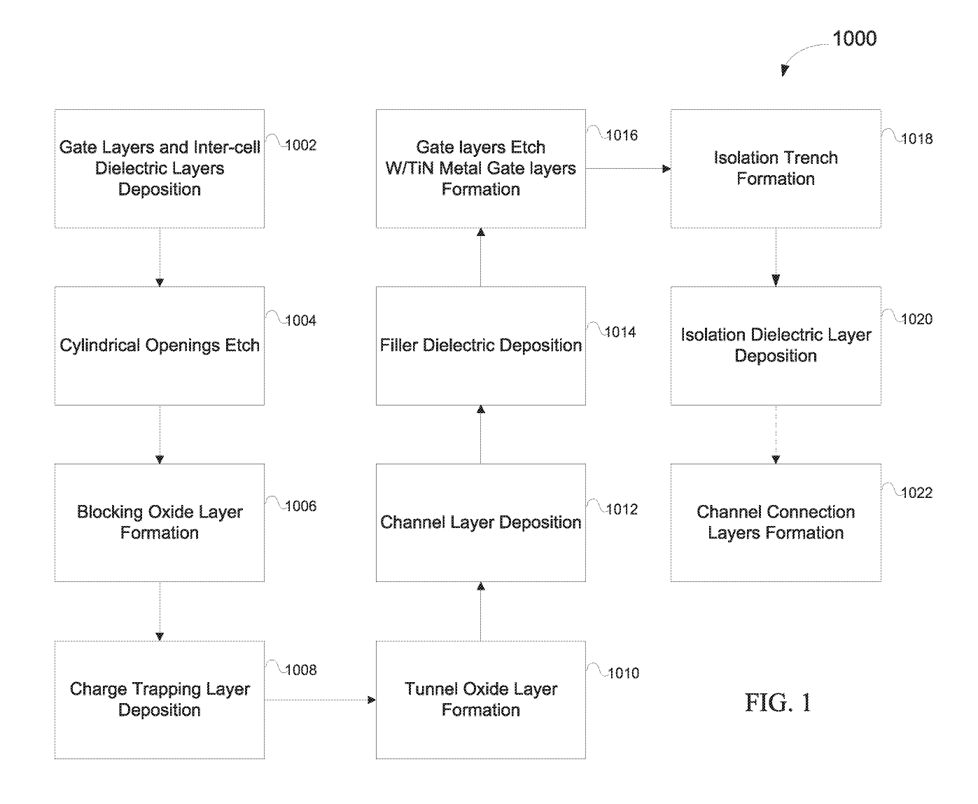

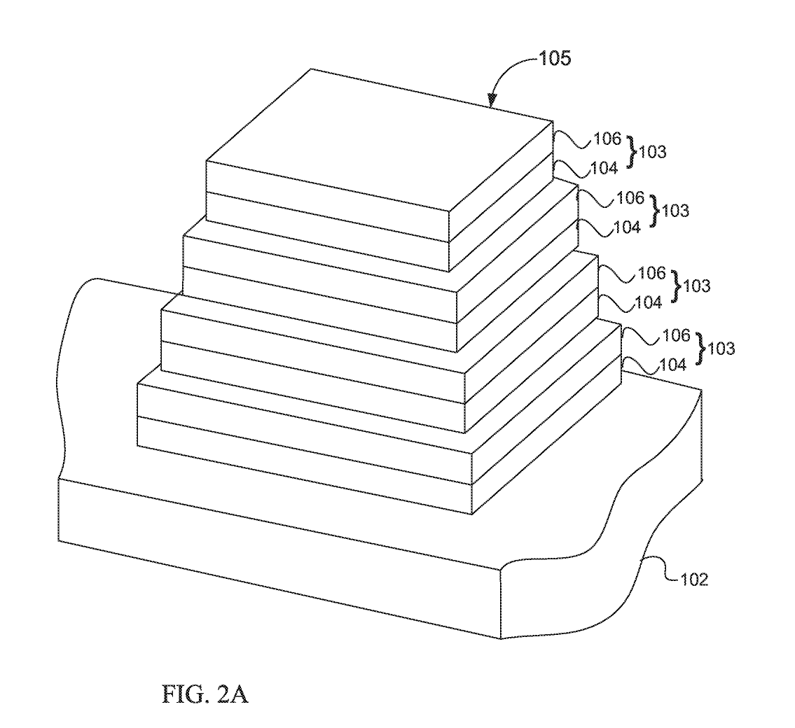

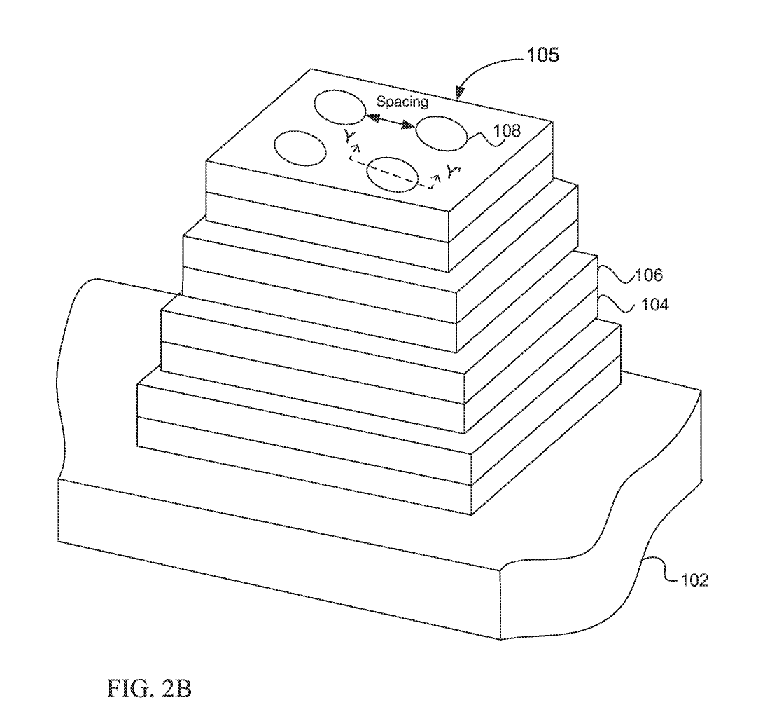

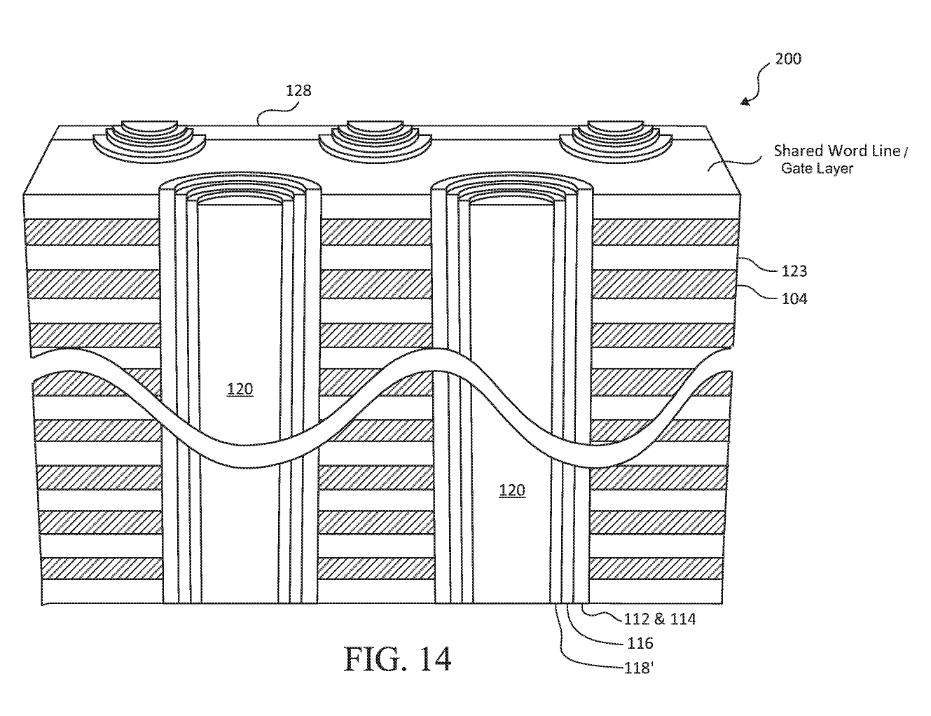

The NVM transistor may include memory transistors or devices implemented related to Silicon-Oxide-Nitride-Oxide-Silicon (SONOS) or floating gate technology. An embodiment of a method for fabricating a vertical memory device including string(s) of NV memory elements will now be described in detail with reference to FIG. 1 and FIGS. 2A through 13. FIG. 1 is a flowchart illustrating an embodiment of a method or process flow for fabricating a 3D or vertical NV memory device. FIGS. 2A-13 are block and schematic diagrams illustrating cross-sectional and isometric views of a portion of a vertical NV memory device during fabrication of the memory cells according to the method of FIG. 1. FIG. 14 is a representative diagram illustrating a cross-sectional view of a portion of one embodiment of the finished memory device or array. In one embodiment, vertical NV memory device may include a single or multiple vertical NAND memory cell strings.

Referring to FIG. 1 and FIG. 2A, the fabrication process begins with forming a stack 105 of alternating layers of multiple inter-cell dielectric layers 104 and gate layers 106 over a substrate or wafer 102, in step 1002. Wafer 102 may be a bulk wafer composed of any single crystal material suitable for semiconductor device fabrication, or may include a top epitaxial layer of a suitable material formed on a wafer. In one embodiment, suitable materials for wafer 102 include, but are not limited to, silicon, germanium, silicon-germanium or a Group III-V compound semiconductor material. In one embodiment, stack 105 is formed adopting a stair geometry having a plurality of steps of potentially up to about 60 steps. In one embodiment, each step includes an inter-cell dielectric layer 104 and a gate layer 106 to form a pair 103. According to the stair geometry, in one embodiment, the surface area of inter-cell dielectric layer 104 and gate layer 106 pair 103 may get smaller as they are disposed higher in the stack 105. The stair geometry of stack 105 may facilitate more effective connections to gate layers 106. In other embodiments, stack 105 may adopt other configurations and all inter-cell dielectric layer 104 and gate layer 106 pairs 103 may have approximately the same surface area. As illustrated in FIG. 2A, inter-cell dielectric layer 104 of the bottom pair 103 may be disposed directly overlying and in contact with wafer 102, or there may be intervening layers between them (not shown). In one embodiment, the intervening layers may be dielectric layers, gate layers, semiconductor layers used to manufacture intervening devices between the string of NV memory cells and wafer 102. In another embodiment, there may be additional layers formed over the top inter-cell dielectric layer 104 and gate layer 106 pair 103 of the stack 105. In one embodiment, the bottom intervening layers and top additional layers may be utilized to form semiconductor devices other than NV memory cells, such as field-effect transistors (FET) or connecting elements according to system requirements.

In one embodiment, inter-cell dielectric layers 104 may be formed by any suitable deposition methods known in the art, such as sputtering, chemical vapor deposition (CVD), molecular beam epitaxy (MBE), atomic layer deposition (ALD), etc. The inter-cell dielectric layers 104 may include silicon dioxide (SiO₂) or other dielectric material having a thickness of from about 20 nanometers (nm) to about 50 nm. In some embodiments, inter-cell layers 104 may have variable thicknesses throughout stack 105. In one alternative embodiment, some or all of the inter-cell dielectric layers 104 may be grown by a thermal oxidation process, in-situ steam generation process or plasma or radical oxidation technique.

Generally, gate layers 106 may eventually become or electrically coupled to control gates of NV transistors in vertical NV memory device 90. In one embodiment, gate layers 106 may be coupled to word lines. As best shown in FIG. 2A, gate layers 106 may be formed over a top surface of each inter-cell dielectric layer 104. In one embodiment, when polysilicon control gates are desired, gate layers 106 may be formed by a deposition process like those discussed above and include a single doped polysilicon layer, either positively or negatively doped (p+ doped or n+ doped) with appropriate dopants and concentration known in the art. The gate layers 106 may have a thickness of from about 30 nm to about 60 nm. In some embodiments, gate layers 106 may have variable thicknesses throughout stack 105. In one alternative embodiment, when metal control gates are desired, gate layers 106 may be formed by a deposition process and composed of a single layer of silicon nitride (Si₃N₄) having a thickness of from about 30 nm to about 60 nm. Gate layers 106 that are composed of silicon nitride, may then be replaced by or converted to metal gate layers 123 in step 1016, which will be discussed in later sections.

Referring to FIG. 1 and FIG. 2B, vertical cylindrical openings 108, which are substantially perpendicular to wafer 102, may be formed in locations where vertical channels of NV transistor strings of vertical NV memory device 90 may be subsequently formed, in step 1004. It is the understanding that the vertical axis of cylindrical openings 108 may be disposed at a right angle (90°) or an approximate right angle to the top surface of wafer 102. In one embodiment, cylindrical openings 108 may be formed by etching stack 105 using suitable etching processes, such as dry plasma etching, wet etching, etc. In one embodiment, cylindrical openings 108 may be etched to extend beyond a top surface of wafer 102. Optical emission intensity and/or spectroscopic reflectometry technique may be used to detect the end point of and subsequently terminate the cylindrical openings 108 formation process. Cylindrical openings 108 may have an approximately uniform diameter 110 of from about 60 nm to about 130 nm throughout the entirety of stack 105. In other embodiments, cylindrical openings 108 may have a variable cross-sectional diameter, such as a tapered cylindrical shape. In one embodiment, a single stack 105 of vertical NV memory device 90 may include over a million cylindrical openings 108. To ensure proper operations and insulation of the vertical NV memory device 90, each cylindrical opening 108 may be distributed to maintain a minimum spacing, the distance from the perimeter of one cylindrical opening 108 to another. In one embodiment, the minimum spacing may be maintained at about 20 nm to about 130 nm. In another embodiment, cylindrical openings 108 may be distributed such that NV memory cells to be formed may share the same set of control gates and connections to the same set of word lines.

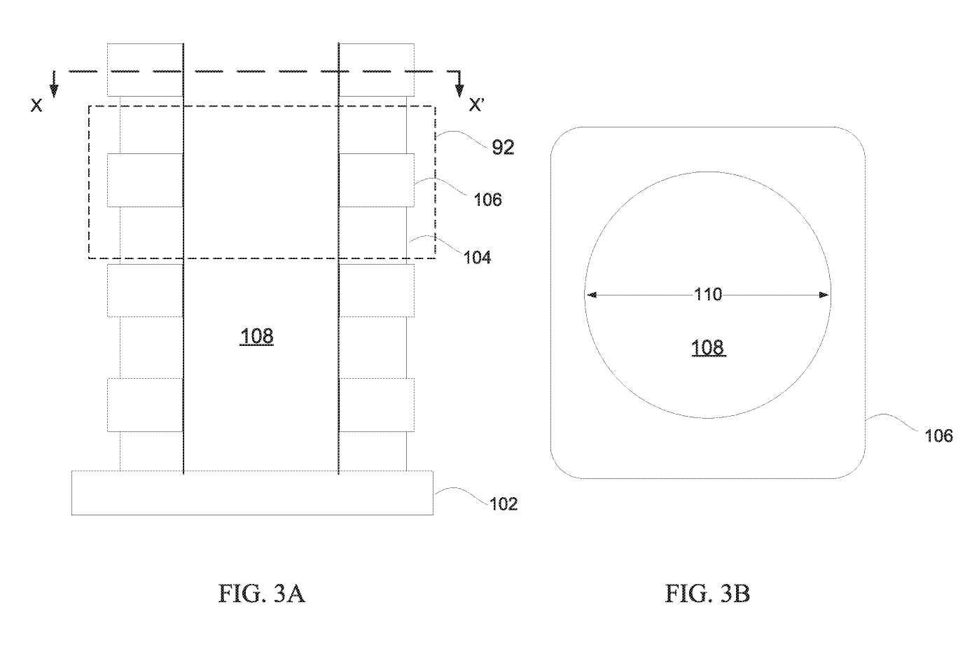

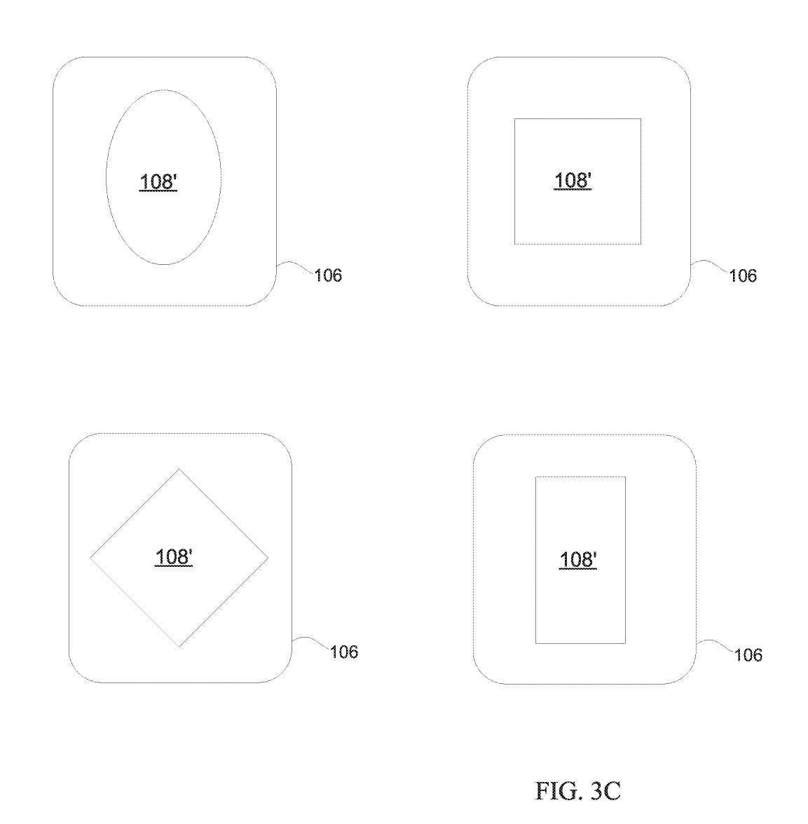

FIG. 3A is a side cross-sectional view along line Y-Y′ of FIG. 2B and FIG. 3B is a top cross-sectional view along X-X′ of FIG. 3A. Referring to FIG. 1, FIGS. 3A and 3B, a portion of vertical NV memory device 90 featuring a single cylindrical opening 108, having four alternating inter-cell dielectric layers 104 and gate layers 106, is illustrated. It should be understood that this is an exemplary embodiment to illustrate the subject matter as vertical NV memory device 90 may have other quantities and combinations of cylindrical openings 108, alternating inter-cell dielectric layers 104 and gate layers 106. Moreover, a vertical NV memory device 90 may include additional semiconductor devices formed at its two ends (in top additional layers and bottom intervening layers as discussed above). A vertical NV memory device 90 that has multiple cylindrical openings 108 may contain multiple NV memory cell strings, each may be fabricated in similar processes, either concurrently or sequentially. In one embodiment, a vertical NAND memory device 90 may be formed in cylindrical opening 108 by forming a string of NV memory cells connected in series. Each NV memory cell may be formed in the area 92 which includes two inter-cell dielectric layers 104 and one gate layer 106. In one embodiment, NV memory cells of the same string may be coupled in series, which resembles a NAND flash memory cell string embodiment. As best illustrated in FIG. 3B, cylindrical opening 108 may have a circular cross-section with a diameter 110 of from about 60 nm to about 130 nm. In other embodiments, as best illustrated in FIG. 3C, cylindrical opening 108′ may have a cross-section of other shapes having a similar or equal cross-sectional area to the circular shape cylindrical opening 108, such as a square, a rectangle, a diamond, an oval, etc. In some embodiments, cylindrical openings 108′ of other shapes may also maintain a minimum spacing at about 20 nm to about 130 nm from one another.

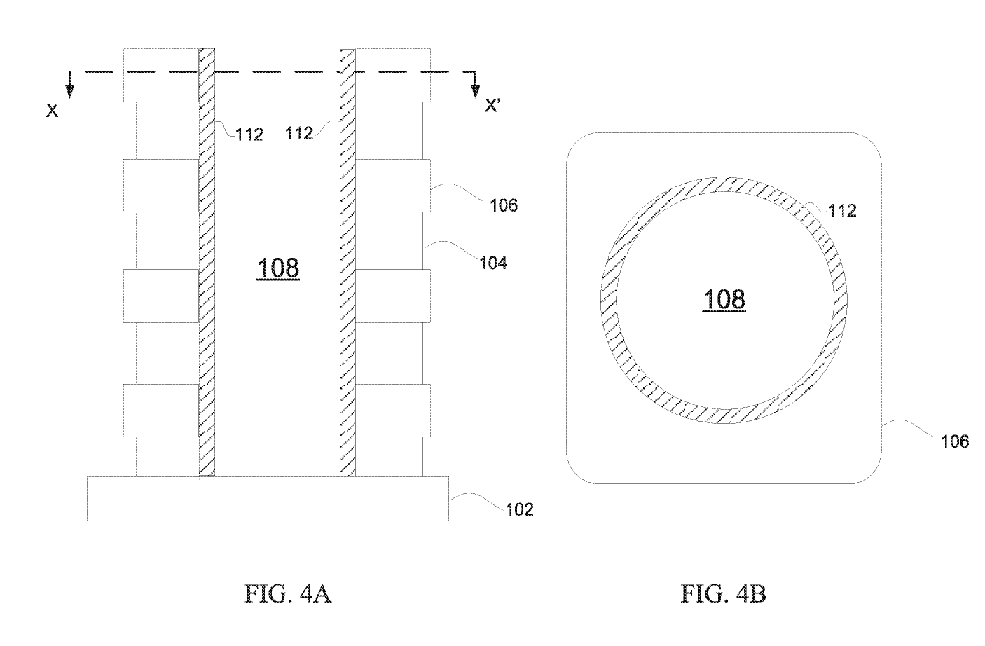

FIG. 4A is a side cross-sectional view of one embodiment of a portion of vertical NV memory device 90 and FIG. 4B is a top cross-sectional view along X-X′ of FIG. 4A. Referring to FIG. 1, FIGS. 4A and 4B, blocking dielectric layer 112 is formed in cylindrical opening 108 in step 1006. In one embodiment, blocking dielectric layer 112 may include a single layer or multiple layers, and may include layer(s) of SiO₂ or other dielectric materials coating the inside wall of cylindrical opening 108. The blocking dielectric layer 112 may be formed by suitable conformal deposition process, such as CVD and ALD, and have a relatively uniform thickness of about 30 Å to about 70 Å. For example, the blocking oxide layer 112 may be deposited by a CVD process using a process gas including gas mixtures of silane or dichlorosilane (DCS) and an oxygen-containing gas, such as O₂ or N₂O, in ratios and at flow rates tailored to provide a silicon dioxide (SiO₂) blocking dielectric layer 112. In another embodiment, blocking dielectric layer 112 may include other high-k dielectric materials, such as hafnium oxide, alternatively or additionally to silicon dioxide. In various other embodiments, blocking dielectric layer 112 may be formed by thermal oxidation or in-situ steam generation or plasma, radical, or other oxidation processes.

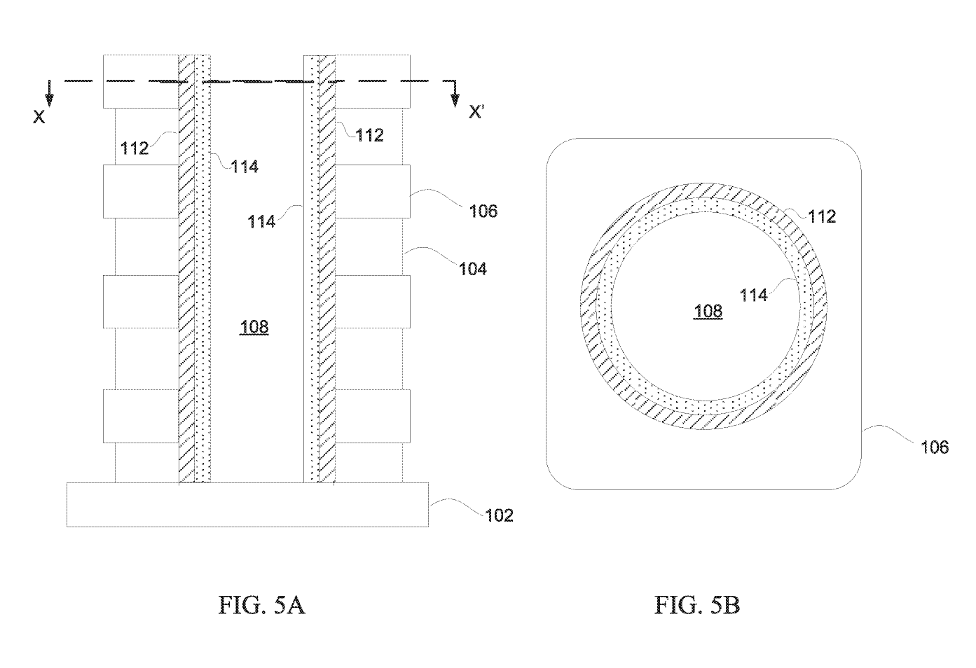

FIG. 5A is a side cross-sectional view of one embodiment of a portion of vertical NV memory device 90 and FIG. 5B is a top cross-sectional view along X-X′ of FIG. 5A. Referring to FIG. 1 and FIGS. 5A and 5B, charge-trapping layer 114 is formed in cylindrical opening 108, in step 1008. In various embodiments, charge-trapping layer 114 is a single layer and may include a layer of silicon nitride and/or silicon oxynitride formed on or overlying or in contact with the blocking dielectric layer 112. The charge-trapping layer 114 may be formed by suitable conformal deposition process, such as CVD and ALD. In one embodiment, charge-trapping layer 114 may have a relatively uniform thickness of from about 50 Å to about 100 Å. As best shown in FIG. 5A, charge-trapping layer 114 is a continuous layer, or coating the entire length of cylindrical opening 108. In one embodiment, charge-trapping layer 114 may cover the cylindrical opening 108 only partially. NV memory cells formed in different steps in the stack 105 do not interfere with one another because charge carriers trapped in the charge-trapping layer 114 may not move from layer to layer vertically along cylindrical opening 108. The electric fields associated with gate layers 106 closely confine charge carriers in the charge-trapping layer 114 to the gate layer 106 they are trapped in.

In another embodiment, charge trapping layer 114 may have multiple layers including at least a first charge-trapping layer that is formed on or overlying or in contact with the blocking dielectric layer 112, and a second charge-trapping layer that is formed on or overlying or in contact with the first charge-trapping layer. The first charge-trapping layer may be oxygen-lean relative to the second charge-trapping layer and may comprise a majority of a charge traps distributed in multi-layer charge-trapping layer 114. In one embodiment, the first charge-trapping layer may include a silicon nitride and silicon oxynitride layer having a stoichiometric composition of oxygen, nitrogen and/or silicon that is different from that of the second charge-trapping layer. The first charge-trapping layer may include a silicon oxynitride layer which may be formed or deposited by a CVD process using a process gas including DCS/NH₃ and N₂O/NH₃ gas mixtures in ratios and at flow rates tailored to provide a silicon-rich, oxygen-lean top nitride layer. In various other embodiments, mono-silane SiH₄ (MS), di-silane Si₂H₆ (DS), tetra-chloro-silane SiCl₄ (TCS), and hexa-chloro-di-silane Si₂Cl₆ (HCD) may be used as a source of silicon in the CVD process. The second charge-trapping layer of a multi-layer charge-trapping layer 114′ may include a silicon nitride (Si₃N₄), silicon-rich silicon nitride or a silicon oxynitride (SiOₓN_{y}) layer. For example, the second charge-trapping layer may include a silicon oxynitride layer formed by a CVD process using dichlorosilane (DCS)/ammonia (NH₃) and nitrous oxide (N₂O)/NH₃ gas mixtures in ratios and at flow rates tailored to provide a silicon-rich and oxygen-rich oxynitride layer. In one alternative embodiment, the stoichiometric composition of oxygen, nitrogen and/or silicon of first and second charge-trapping layers may be identical or approximate to one another.

In another embodiment, there may be a dielectric and/or oxide layer (not shown) formed between the first and second charge-trapping layers, making the multi-layer charge trapping layer 114′ an NON structure/stack. In some embodiments, the multi-layer charge-trapping layer 114′ is a split charge-trapping layer, further including a thin, middle oxide layer (not shown) separating the first and second charge-trapping layers. The middle oxide layer substantially reduces the probability of electron charge that accumulates at the boundaries of the first charge-trapping layer during programming from tunneling into the second charge-trapping layer, resulting in lower leakage current than for conventional memory devices. In one embodiment, the middle oxide layer is formed by oxidizing to a chosen depth using thermal or radical oxidation or deposition processes, such as CVD and ALD.

As used herein, the terms “oxygen-rich” and “silicon-rich” are relative to a stoichiometric silicon nitride, or “nitride,” commonly employed in the art having a composition of (Si₃N₄) and with a refractive index (RI) of approximately 2.0 at 633 nm. Thus, “oxygen-rich” silicon oxynitride corresponds to a shift from stoichiometric silicon nitride toward a higher weight percentage of silicon and oxygen (i.e. reduction of nitrogen). An oxygen rich silicon oxynitride film is therefore more like silicon dioxide and the RI is reduced toward the 1.45 RI of pure silicon dioxide. Similarly, films described herein as “silicon-rich” correspond to a shift from stoichiometric silicon nitride toward a higher weight percentage of silicon with less oxygen than an “oxygen-rich” film. A silicon-rich silicon oxynitride film is therefore more like silicon and the RI is increased toward the 3.5 RI of pure silicon.

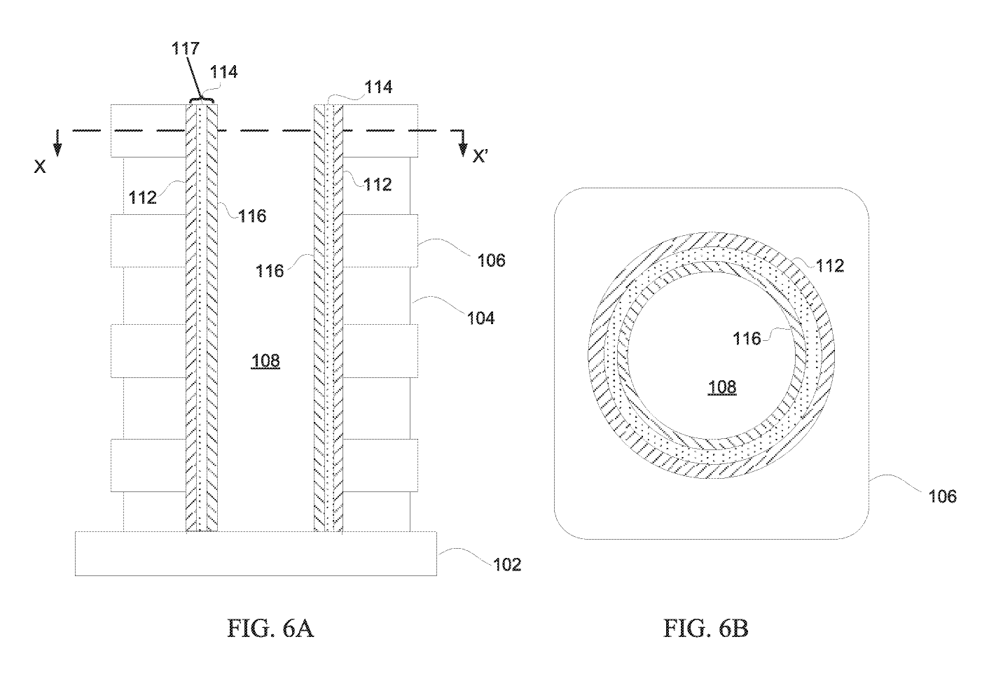

FIG. 6A is a side cross-sectional view of one embodiment of a portion of vertical NV memory device 90 and FIG. 6B is a top cross-sectional view along X-X′ of FIG. 6A. Referring to FIG. 1 and FIGS. 6A and 6B, tunnel dielectric layer 116 is formed in cylindrical opening 108, in step 1010. In one embodiment, tunnel dielectric layer 116 may be formed on or overlying or in contact with the charge-trapping layer 114 within cylindrical opening 108. For example, a layer of dielectric material may be deposited by CVD or ALD process. In various embodiments, the layer of dielectric material may include, but not limited to silicon dioxide, silicon oxynitride, silicon nitride, aluminum oxide, hafnium oxide, zirconium oxide, hafnium silicate, zirconium silicate, hafnium oxynitride, hafnium zirconium oxide and lanthanum oxide. Generally, tunnel dielectric layer 116 has a relatively uniform thickness of from about 20 Å to about 50 Å or other thicknesses suitable to allow charge carriers to tunnel into the charge-trapping layer 114 under an applied control gate bias while maintaining a suitable barrier to leakage when the applied gate is unbiased. In certain embodiments, tunnel dielectric layer 116 is silicon dioxide, silicon oxynitride, or a combination thereof and can be grown by a thermal oxidation process, using plasma or radical oxidation. In yet another embodiment, tunnel dielectric layer 116 may be a bi-layer dielectric region including a first layer of a material such as, but not limited to, silicon dioxide or silicon oxynitride and a second layer of a material which may include, but is not limited to silicon nitride, aluminum oxide, hafnium oxide, zirconium oxide, hafnium silicate, zirconium silicate, hafnium oxynitride, hafnium zirconium oxide and lanthanum oxide.

In one embodiment, blocking dielectric layer 112, charge trapping layer 114 and tunnel dielectric layer 116 may be referred to collectively as charge trapping dielectric or multi-layer dielectric 107.

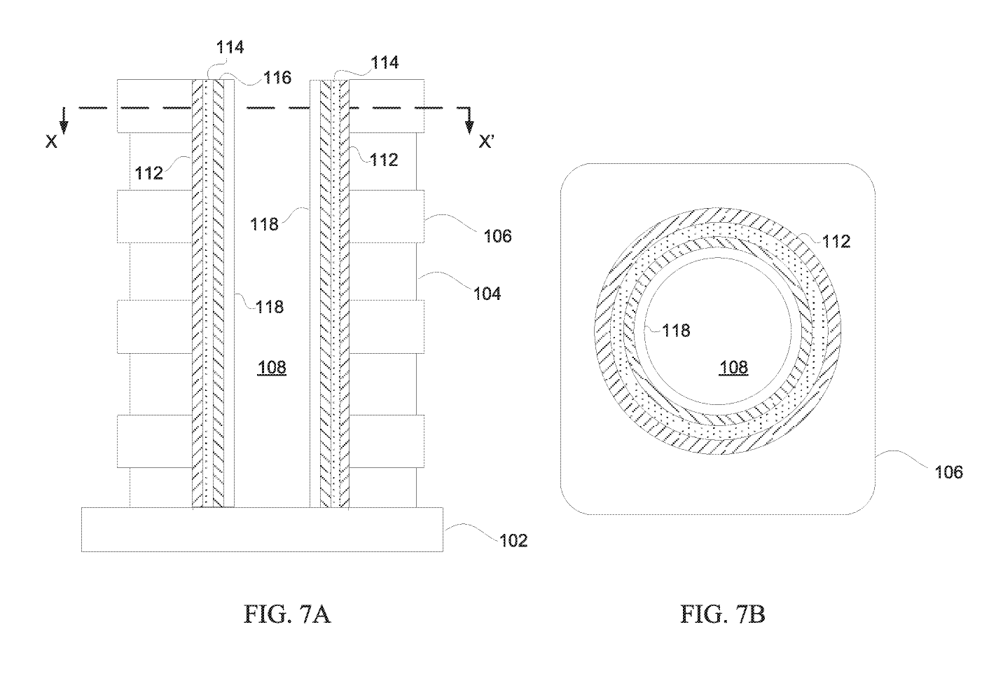

FIG. 7A is a side cross-sectional view of one embodiment of a portion of vertical NV memory device 90 and FIG. 7B is a top cross-sectional view along X-X′ of FIG. 7A. Referring to FIG. 1, FIGS. 7A and 7B, channel layer 118 is formed in cylindrical opening 108, in step 1012. As illustrated in FIG. 7A, channel layer 108 of vertical NV memory device 90 is vertical and substantially perpendicular to a top surface of substrate 102, which has an opposite orientation of the channels in 2D geometry. In one embodiment, channel layer 118 may be formed on, overlying or in contact with the tunnel dielectric layer 116 within cylindrical opening 108. The channel layer 118 may include any suitable semiconductor materials, such as silicon, germanium, silicon germanium, or other compound semiconductor materials, such as III-V, II-VI, or conductive or semiconductive oxides, etc. The semiconductor material may be amorphous, polycrystalline, or single crystal. The channel layer 118 may be formed by any suitable deposition process, such as low pressure chemical vapor deposition (LPCVD), CVD and ALD. In certain embodiments, the semiconductor channel material may be a recrystallized polycrystalline semiconductor material formed by recrystallizing an initially deposited amorphous semiconductor material. In one embodiment, the channel layer 118 may have a relative uniform thickness of from about 50 Å to about 150 Å. In another embodiment, instead of forming a layer overlying the charge-trapping layer 116, the remaining empty space of cylindrical opening 108 is filled completely with semiconductor channel material as mentioned above. In some embodiments, channel layer 118 may contain un-doped or electrically neutral semiconductor channel material as discussed above. Depending on the device performance requirements, in another embodiment, the semiconductor channel material may be lightly doped with positive-typed dopants, such as boron. In one embodiment, channel layer 118 is formed by in-situ boron-doped CVD technique. During the deposition process, approximately 1% to 0.01% of boron source, such as BCl₃ or B₂H₆ in SiH₄ is introduced, and the process is carried out in a temperature at approximately 530° C. In one embodiment, the concentration of dopant in the channel layer 118 may be from about 1e17 cm⁻³ to about 1e20 cm⁻³.

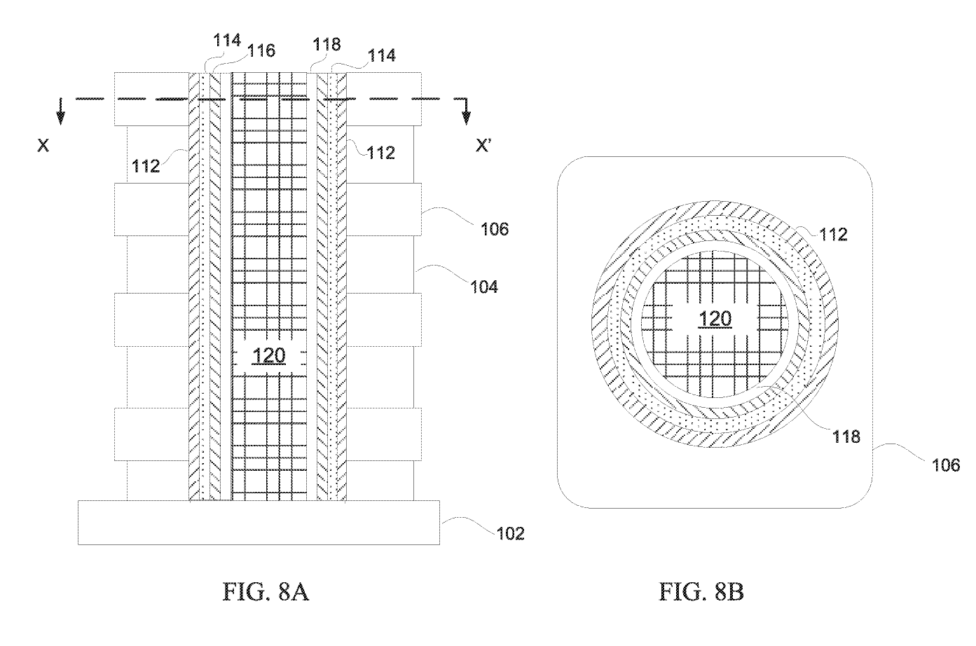

FIG. 8A is a side cross-sectional view of one embodiment of a portion of vertical NV memory device 90 and FIG. 8B is a top cross-sectional view along X-X′ of FIG. 8A. Referring to FIG. 1, FIGS. 8A and 8B, dielectric filler 120 is formed in cylindrical opening 108 to fill out empty space in cylindrical opening 108 after channel layer 118 is formed, in step 1014. In one embodiment, dielectric filler 120 includes dielectric materials, such as silicon dioxide, silicon nitride, and silicon oxynitride, and is formed by deposition methods, such as CVD or ALD, or oxidation methods, such as plasma or radical oxidation technique or thermal RTO.

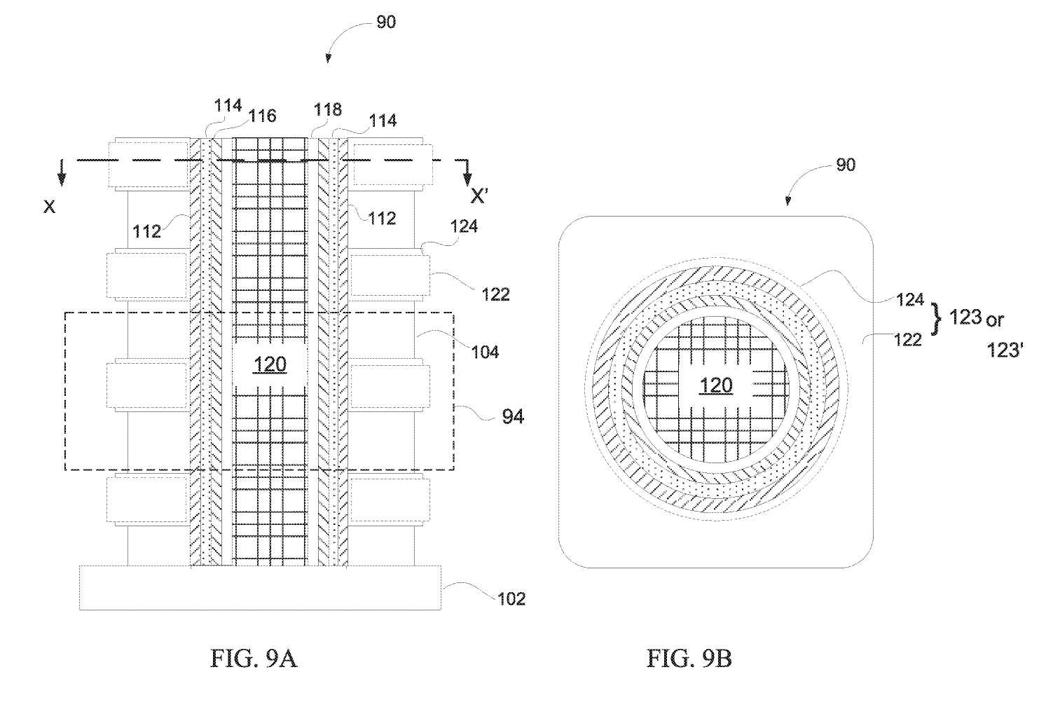

FIG. 9A is a side cross-sectional view of one embodiment of a portion of vertical NV memory device 90 and FIG. 9B is a top cross-sectional view along X-X′ of FIG. 8A. Referring to FIG. 1, FIGS. 9A and 9B, metal gate layer 123 is formed to replace gate layers 106 disposed between inter-cell dielectric layers 104 in stack 105, in step 1016. In one embodiment, gate layers 106, which include silicon nitride, are firstly removed using a wet etch process. Vertical NV memory device 90 is dipped in wet etch chemical, such as phosphoric acid (H₃PO₄) in a temperature range of from about 150° C. to about 170° C., for about 50 minutes (mins) to about 120 mins. In one embodiment, photoresist layers or hard marks (not shown) may be formed to protect other layers from etchants. Once gate layers 106 are removed, the removed gate layers 106 are then replaced by layers of metal gate layers 123, in which each metal gate layer 123 includes a gate coating layer 124 and a gate filler layer 122. In one embodiment, the process may start by forming gate coating layer 124 of titanium nitride (TiN) using a suitable deposition process, such as metalorganic CVD (MOCVD) or ALD. When the process is completed, the deposited layer becomes gate coating layer 124 that coats or lines the space defined by two neighboring inter-cell dielectric layers 104 and blocking dielectric layer 112. In various embodiments, the coating of the space may be complete or partial. Subsequently, the remaining space is filled by a layer of conductive material, such as tungsten (W), using a metal CVD process. In one embodiment, TiN coating as the gate coating layer 124 improves surface properties. The combination of TiN and W to form metal gate layer 123 is one of the combinations of the present embodiment. Other combinations using different conductive materials to form metal gate layers 123 may include but are not limited to metal nitrides, metal carbides, metal silicides, hafnium, zirconium, titanium, tantalum, aluminum, ruthenium, palladium, platinum, cobalt and nickel, which are known in the art and may be adopted. In one alternative embodiment, instead of forming metal gate layers 123, polysilicon gate layers 123′ is formed by deposition process, such as CVD and ALD. In one embodiment, polysilicon doped with appropriate dopants at an operational concentration that are known in the art may be deposited.

In one embodiment, as shown in FIG. 9A, after metal gate layers 123 or polysilicon layers 123′ are formed, vertical NV memory device 90 is primarily completed. In one embodiment, the completed vertical NV memory device 90 includes a string of NV memory cells 94 connected in series, in which metal gate layers 123 or polysilicon layers 123′ correspond to control gates and portions of channel layer 118 adjacent to inter-cell dielectric layers 104 to source/drain regions of individual NV memory cells 94. As mentioned, there may be semiconductor devices other than NV memory cells 94, such as field-effect transistors (FET) or connecting elements formed in the bottom intervening layers and top additional layers in stack 105. In one embodiment, channel layer 118 represents a shared channel for all NV memory cells 94 within one cylindrical opening 108 of the vertical NV memory device 90.

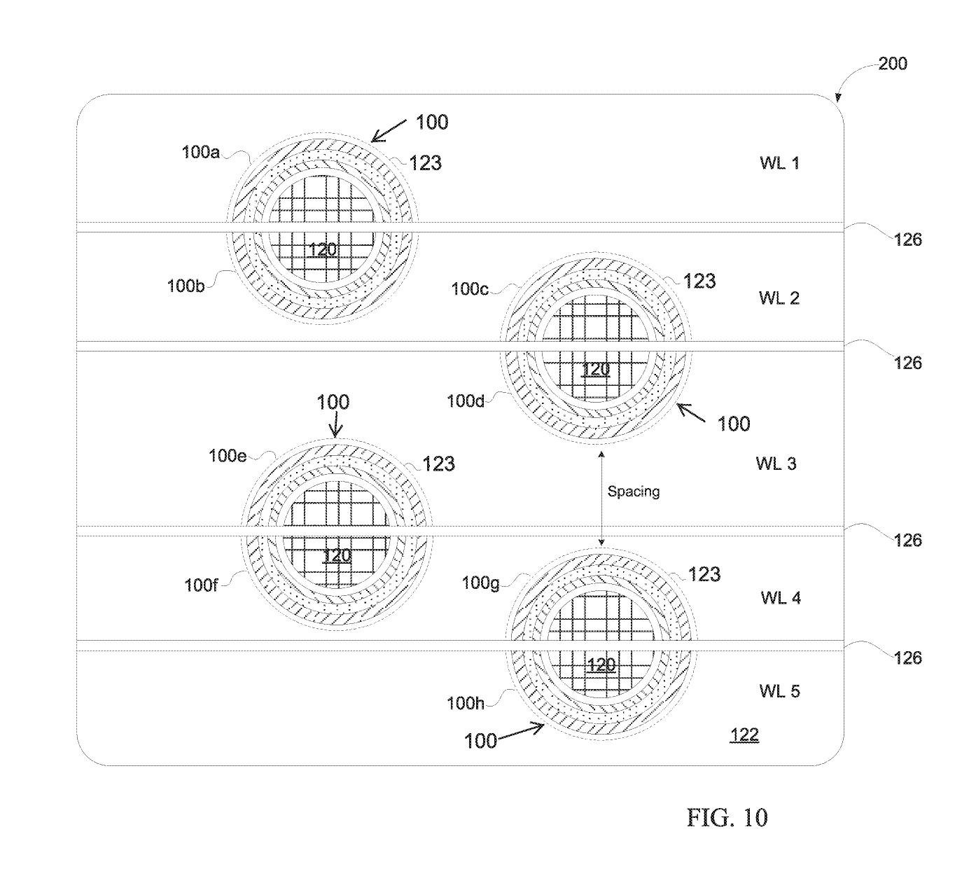

Next, referring to FIG. 1 and FIGS. 10-13, processes to divide vertical NV memory device 90 to increase memory bit density while maintaining the same spacing will be discussed. FIG. 10 is a horizontal cross-sectional view showing a portion of vertical NV memory array 200. As illustrated in FIG. 10, four vertical NV memory cell strings 100 are distributed in a top surface of stack 105, and each vertical NV memory cell string 100 resembles vertical NV memory device 90 as shown in FIGS. 9A and 9B. In one embodiment, before vertical NV memory cell strings 100 are divided, each of them includes a plurality of NV memory cells 94, as shown in FIG. 9A, connected in series. Each NV memory cell 94 on the same layer shares a same metal gate layer 123 which includes gate coating layer 124 and gate filler layer 122. In one embodiment, metal gate layer 123 either functions as a common word line or is coupled to a common word line for NV memory cells 94 of the same vertical layer.

As illustrated in FIG. 10, vertical deep trenches 126 are created to physically separate a single vertical NV memory cell string 100 into two half vertical NV memory cell strings, such as 100a and 100b. In one embodiment, vertical deep trenches 126 may extend substantially from the top surface of stack 105 to wafer 102. In another embodiment, vertical deep trenches 126 may only extend partially along the length of cylindrical opening 108. In various embodiments, vertical deep trenches 126 may also divide semiconductor devices other than NV memory cells, such as field-effect transistors (FET) or connecting elements formed in the bottom intervening layers and top additional layers of the stack 105. Alternatively, at least some of the semiconductor devices other than NV memory cells 94, such as field-effect transistors (FET) or connecting elements formed in the bottom intervening layers and top additional layers in stack 105 may remain intact and are not divided by vertical deep trenches 126.

As a result, for example, vertical NV memory cell string 100 that has a circular cross-section may be divided into two half vertical NV memory cell strings 100a and 100b that have a semi-circular cross-section. In one embodiment, the two half vertical NV memory cell strings 100a and 100b may have a similar or equal cross-sectional area. In one embodiment, half vertical NV memory cell strings 100a and 100b may be electrically insulated from one another and operate individually as a memory cell string, effectively doubling the memory bit density of vertical NV memory cell string 100. As illustrated in FIG. 10, vertical deep trenches 126 may extend beyond boundaries of vertical NV memory cell strings 100. In other embodiments, vertical deep trenches 126 may be created to divide NV memory cell strings 100 that have other cross-sectional shapes, such as oval, diamond, rectangular, and square as best shown in FIG. 3C. In one embodiment, according to system requirements, vertical deep trenches 126 may be created in a pattern in stack 105 that multiple half vertical NV memory cell strings 100a-h may share a same metal gate layer 123 and therefore a same set of word lines. For example, half vertical NV memory cell strings 100b and 100c share a same word line WL 2, which may also be a part of metal gate layer 123.

In one embodiment, vertical deep trench 126, which has a relative uniform thickness of from about 5 nm to about 25 nm, is formed using a plasma dry etch process, in step 1018. The vertical plasma dry etch process may be carried out in a reactive ion etcher with either an inductively or capacitively coupled plasma source (ICP or CCP, respectively) at pressures from about 5 millitorr (mT) to about 150 mT. The source power of the ICP source or the CCP source is calibrated from about 600 watts to about 2500 watts. The substrate bias is set from about 100 V to about 1000 V, and substrate temperature is set from about 15° C. to about 75° C. In one embodiment, gas chemistry within the reactive ion etcher may be tuned to give approximately equal etch rates for all materials to be etched, including dielectric filler 120 (e.g. SiO₂), channel layer 118 (e.g. Si), tunnel dielectric layer 116 (e.g. SiO₂, Si₃N₄), charge-trapping layer 114 (e.g. Si₃N₄, SiO₂), blocking dielectric layer 112 (e.g. SiO₂, Si₃N₄), and gate layer 123 (e.g. W, TiN, or Poly-Si). A typical gas mixture may include at least one of fluorine-containing or chlorine-containing etchants, such as NF₃, CF₄, Cl₂, CHF₃, CH₂F₂, SiCl₄, to adjust the selectivity of etching and profile. Additives, such as O₂ or CO may be introduced during the etching process to control the polymer formation, as well as argon or alternative inert gases, such as xenon or helium, for sputtering and/or dilution purposes. In one embodiment, optical emission intensity and/or spectroscopic reflectometry technique may be used to detect the end point of and subsequently terminate the dry plasma etching process.

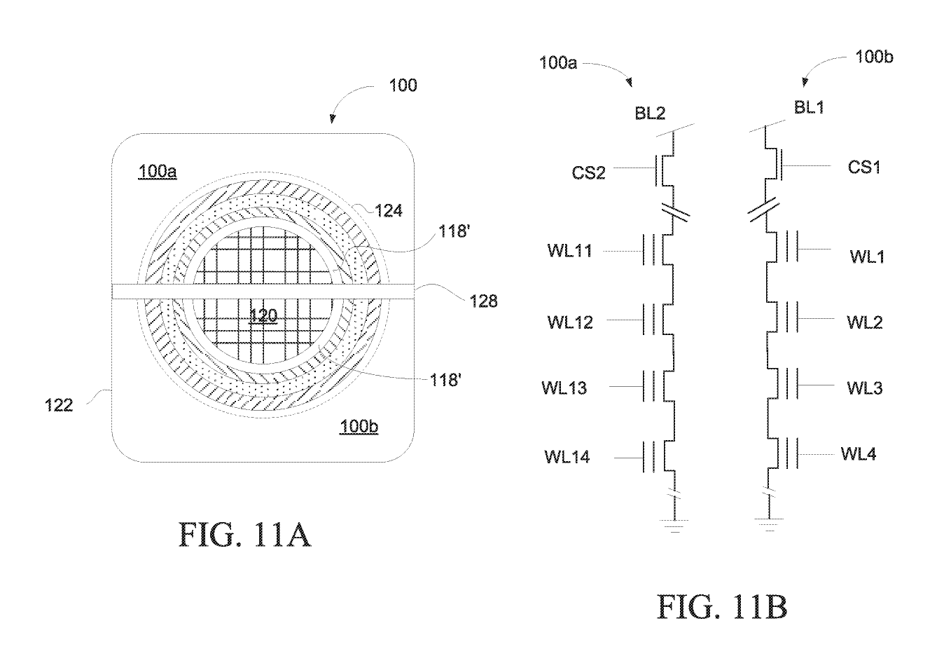

Referring to FIGS. 1 and 11A (horizontal cross-sectional view showing two half vertical NV memory cell strings 100a and 100b), after vertical deep trench 126 is formed, half vertical NV memory cell strings 100a and 100b are electrically insulated from one another. The insulation is further cemented by the formation of isolation dielectric layer or pillar 128. In one embodiment, isolation dielectric layer 128 is formed by depositing dielectric material, such as silicon dioxide, or silicon nitride, to fill vertical deep trench 126, in step 1020. Isolation dielectric layer 128 may be formed by a suitable CVD or ALD process. FIG. 11B illustrates a schematic of the two half vertical NV memory cell strings 100a and 100b. As shown in FIG. 11B, half vertical NV memory cell strings 100a and 100b do not share channel layer 118 as they each have their own channel layer 118′, and are completely isolated from one another by the isolation dielectric layer 128. Consequently, half vertical NV memory cell strings 100a and 100b may be operated individually as a memory device, effectively doubling the memory bits of vertical NV memory cell string 100 prior to the division process. In one embodiment, half vertical NV memory cell strings 100a and 100b may be connected to different bit lines (BL1 and BL2) and two separate sets of word lines (WL 1-4, WL 11-14) and control signals (CS1, CS2). Alternatively, half vertical NV memory cell strings 100a and 100b may be connected to a same set of word lines, control signals, and/or other connecting, semiconductor elements.

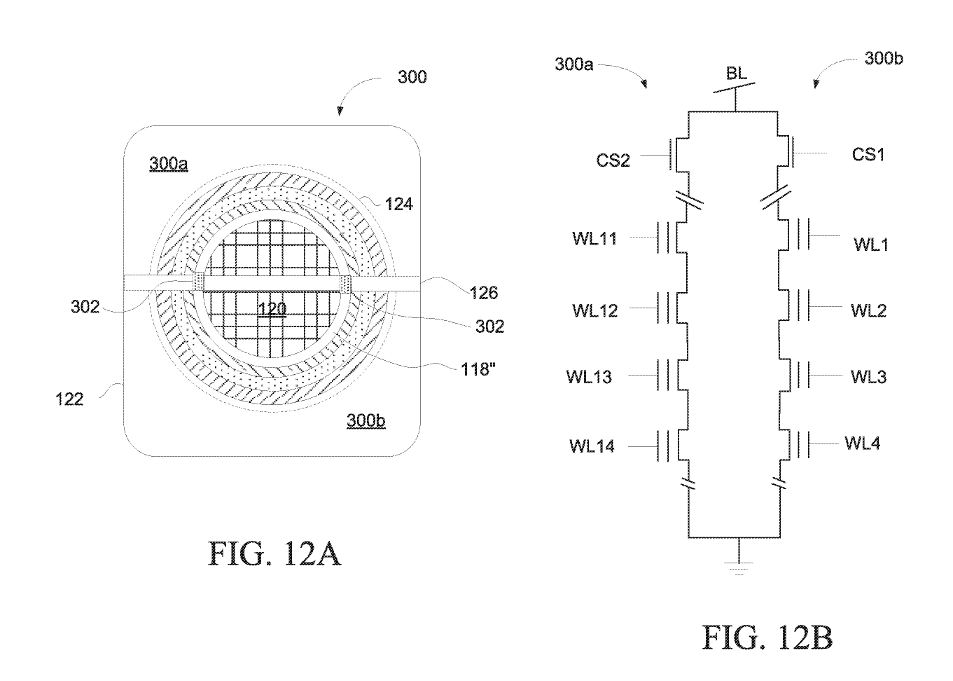

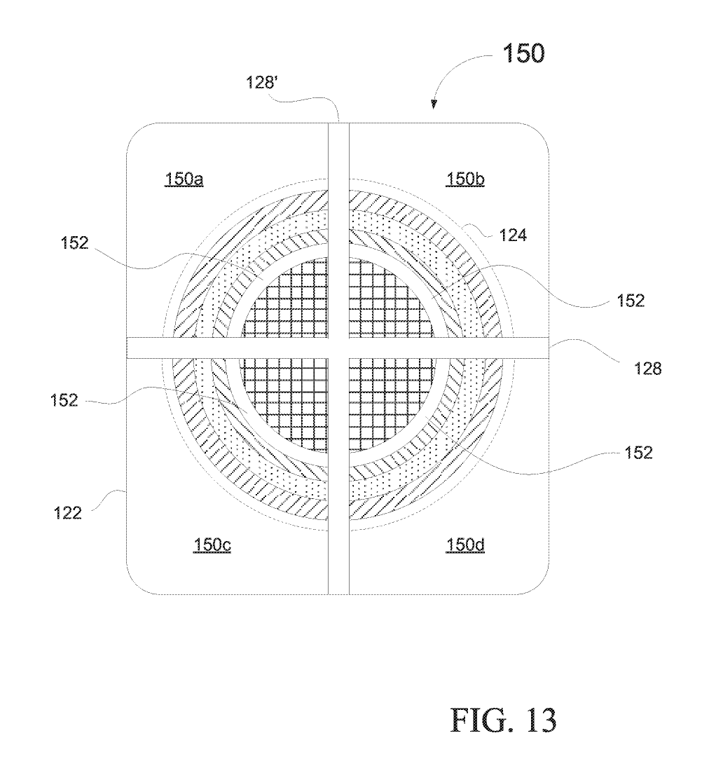

FIG. 12A illustrates a horizontal cross-sectional view showing two half vertical NV memory cell strings 300a and 300b including a restored channel layer 118″. After vertical deep trench 126 is formed, half vertical NV memory cell strings 300a and 300b are isolated from one another. In one embodiment, optionally, the two divided channel layers 118′ may be re-connected by a selective silicon growth process, in step 1022. The selective silicon growth process restores channel layer 118″ by selectively growing channel connection layers or pillars 302 with silicon (un-doped or slightly positively doped) throughout the stack 105 such that half vertical NV memory cell strings 300a and 300b share a common restored channel layer 118″. Subsequently, isolation dielectric layer or pillar 128 is formed by depositing dielectric material, such as silicon dioxide, or silicon nitride, to fill the rest of vertical deep trench 126. FIG. 12B illustrates a schematic diagram showing half vertical NV memory cell strings 300a and 300b. As best shown in FIG. 12B, half vertical NV memory cell strings 300a and 300b may have a common source/drain path (restored channel layer 118″) and coupled to the same bit line (BL) but have their own charge trapping dielectric and metal gate layers 123. In one embodiment, half vertical NV memory cell strings 300a and 300b may be controlled by separate control signal (CS1, CS2) and control gate connection (WL11-14, WL 1-4).

FIG. 13 illustrates a horizontal cross-sectional view showing four quadrant vertical NV memory cell strings 150a-d divided from one vertical NV memory cell string 150. In one embodiment, instead of having one vertical isolation dielectric layer 128, an additional vertical isolation dielectric layer 128′, which is substantially perpendicular to vertical isolation dielectric layer 128, is formed to divide vertical NV memory cell string 150 into four quadrant vertical NV memory cell strings 150a-d. In one embodiment, an additional vertical isolation dielectric layer 128′ is formed in a similar process as the vertical isolation dielectric layer 128, either concurrently or sequentially. In some embodiments, depending on the system requirements, quadrant vertical NV memory cell strings 150a-d may or may not share control gate connections to word lines and control signals. In other embodiments, quadrant vertical NV memory cell strings 150a-d may or may not share common channel layers 118 which may be formed by the aforementioned selective silicon growth technique in step 1022.

FIG. 14 is a block diagram illustrating a cross-sectional view of a portion of vertical NV memory array 200 fabricated according to the method of FIGS. 1 and 2A-13. As illustrated, while the five half vertical NV memory cell strings shown may be operated individually to increase memory bits of the entire array 200, they may share a same set of control gates and/or word lines. In one embodiment, vertical NV memory array 200 may include multiple portions as illustrated in FIG. 14 in which each portion may share a same set of word lines.

Thus, embodiments of divided vertical/3D NV memory devices/strings/apparatus and methods of fabricating the same have been described. Although the present disclosure has been described with reference to specific exemplary embodiments, it will be evident that various modifications and changes may be made to these embodiments without departing from the broader spirit and scope of the disclosure. Accordingly, the specification and drawings are to be regarded in an illustrative rather than a restrictive sense.

The Abstract of the Disclosure is provided to comply with 37 C.F.R. § 1.72(b), requiring an abstract that will allow the reader to quickly ascertain the nature of one or more embodiments of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

Reference in the description to one embodiment or an embodiment means that a particular feature, structure, or characteristic described in connection with the embodiment is included in at least one embodiment of the circuit or method. The appearances of the phrase one embodiment in various places in the specification do not necessarily all refer to the same embodiment.

In the foregoing specification, the subject matter has been described with reference to specific exemplary embodiments thereof. It will, however, be evident that various modifications and changes may be made thereto without departing from the broader spirit and scope of the subject matter as set forth in the appended claims. The specification and drawings are, accordingly, to be regarded in an illustrative sense rather than a restrictive sense.

1-20. (canceled)

21. A method comprising:
forming a stack of alternating layers of a first material and a second material over a substrate;
forming an opening in the stack of alternating layers;
forming a multi-layer dielectric on an inside wall of the opening, and a charge-trapping layer overlying the blocking layer;
forming a channel layer overlying the multi-layer dielectric;
forming a first vertical trench substantially perpendicular to the substrate and dividing the multilayer dielectric and channel layer to form a plurality of vertical memory cell strings, the plurality of vertical memory cell strings including first and second memory cell strings;
forming at least one channel connection pillar in the first vertical trench electrically and physically reconnecting channel layers of the first and second memory cell strings; and
forming a first isolation dielectric layer in the first vertical trench.

22. The method of claim 21, wherein forming the channel connection pillar comprises using a selective silicon growth process to form the channel connection pillar.

23. The method of claim 22, wherein the channel connection pillar comprises un-doped silicon.

24. The method of claim 22, wherein the channel connection pillar comprises doped silicon.

25. The method of claim 21, wherein the channel layer comprises a recrystallized polycrystalline semiconductor material formed by recrystallizing an initially deposited amorphous semiconductor material.

26. The method of claim 21, wherein the first material comprises a dielectric material and the second material comprises a sacrificial material, and the method further comprises after forming the channel layer, removing the sacrificial gate layer using a wet etch process, and depositing a conductive material in contact with the multilayer dielectric to form a gate layer.

27. The method of claim 26, wherein the conductive material comprises a doped polysilicon.

28. The method of claim 26, wherein the conductive material comprises a metal.

29. The method of claim 21, wherein the multi-layer dielectric comprises a blocking layer overlying the inside wall of the opening, and a charge-trapping layer overlying the blocking layer.

30. The method of claim 29, wherein the charge-trapping layer comprises a first charge-trapping layer overlying the blocking layer and a second charge-trapping layer overlying the first charge-trapping layer, wherein the first charge-trapping layer is oxygen-lean relative to the second charge-trapping layer.

31. The method of claim 29, further comprising a thin, middle oxide layer separating the first and second charge-trapping layers, wherein the middle oxide layer is formed by oxidizing a portion of the first charge-trapping layer prior to forming the second charge-trapping layer.

32. A method, comprising:
forming a plurality of vertical memory cell strings within an opening disposed in a stack of alternating layers of a first layer and a second layer over a substrate, wherein forming the plurality of vertical memory cell strings comprises:
forming a multi-layer dielectric including a blocking layer overlying an inside wall of the opening, and a charge-trapping layer overlying the blocking layer;
forming a channel layer overlying the multi-layer dielectric;
forming a first vertical trench substantially perpendicular to the substrate and dividing the multilayer dielectric and channel layer to form the plurality of vertical memory cell strings, wherein the plurality of vertical memory cell strings include first and second memory cell strings;
reconnecting channel layers of the first and second memory cell strings; and
forming a first isolation dielectric layer in the first vertical trench,
wherein reconnecting the channel layer comprises forming at least one channel connection pillar in the first vertical trench electrically and physically connects the channel layers of the first and second memory cell strings.

33. The method of claim 32, wherein reconnecting the channel layer comprises using a selective silicon growth process to form the channel connection pillar.

34. The method of claim 33, wherein the channel connection pillar comprises un-doped silicon.

35. The method of claim 32, wherein the charge-trapping layer comprises a first charge-trapping layer overlying the blocking layer and a second charge-trapping layer overlying the first charge-trapping layer, wherein the first charge-trapping layer is oxygen-lean relative to the second charge-trapping layer.

36. The method of claim 35, further comprising a thin, middle oxide layer separating the first and second charge-trapping layers.

37. The method of claim 36 wherein the middle oxide layer is formed by oxidizing a portion of the first charge-trapping layer prior to forming the second charge-trapping layer.

38. A method, comprising:
forming a three-dimensional (3D) memory array including a plurality of vertical NAND strings, each formed within an opening disposed in a stack of alternating layers of a dielectric layer and a sacrificial gate layer over a substrate, wherein forming the plurality of vertical NAND strings comprises:
forming a multilayer dielectric overlying an inside wall of the opening;
forming a channel layer overlying the multi-layer dielectric;
removing the sacrificial gate layer using a wet etch process;
depositing a conductive material in contact with the multilayer dielectric, to form a gate layer;
forming a vertical trench substantially perpendicular to the substrate and vertically dividing the stack of alternating layers, the multilayer dielectric and the channel layer to form from each of the plurality of vertical NAND strings two half vertical NAND strings separated by the vertical trench;
reconnecting channel layers of the plurality of vertical NAND strings; and
forming an isolation dielectric pillar in the vertical trench,
wherein reconnecting the channel layers comprises forming channel connection pillars in the vertical trench to electrically and physically connects the channel layers of the plurality of vertical NAND strings.

39. The method of claim 38, wherein reconnecting the channel layers comprises using a selective silicon growth process to form the channel connection pillars.

40. The method of claim 38, wherein the channel layer comprises a recrystallized polycrystalline semiconductor material formed by recrystallizing an initially deposited amorphous semiconductor material.
